(19) United States
(12) Patent Application Publication
(10) Pub. No.: US 2025/0356937 A1
(43) Pub. Date: Nov. 20, 2025

(54) MEMORY SUBSYSTEM REDUNDANCY

(71) Applicant: Intel Corporation, Santa Clara, CA (US)

(72) Inventors: Tomer LEVY, Tel Aviv (IL); Yuri AMIROV, Nahariya (IL)

(21) Appl. No.: 19/287,969

(22) Filed: Aug. 1, 2025

(51) Int. Cl. G11C 29/12; G11C 29/38; G11C 29/44

(52) U.S. Cl. CPC G11C 29/1201; G11C 29/38; G11C 29/44

(57) ABSTRACT

An apparatus includes a memory that includes a first memory subchannel and a second memory subchannel; a first memory subsystem; a multiplexer, configured to selectively connect the first memory subsystem to the first memory subchannel or the second memory subchannel; a second memory subsystem, connected to the second memory subchannel; and a processor, configured to control the multiplexer to connect the first memory subsystem to the first memory subchannel according to a first operational mode, or to selectively connect the first memory subsystem to the second memory subchannel according to a second operational mode, based on whether a defect is detected in the second memory subsystem.

### BACKGROUND

A memory may be configured with two subchannels, wherein each subchannel corresponds to a respective subsystem. In this manner, a first subsystem is configured to operate a first subchannel, and a second subsystem is configured to operate a second subchannel. During the manufacturing process, a defect can occur that may render some or all of a particular subsystem defective. Similarly, a given subsystem may be operational at manufacture, but then may become defective thereafter, such as by an event (e.g., high voltage, mechanical damage, etc.) or simply due to the aging process. If a subsystem is or becomes defective, the corresponding subchannel cannot conventionally be operated.

Some memory devices, such as memory devices according to Low Power Double Data Rate 6 (LPDDR6), for example, may include an “efficiency mode” in which a single subsystem can operate two subchannels.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1 depicts a fully-functional system with eight memory channels;

FIG. 2 depicts how a defect requires the disabling of a memory device;

FIG. 3 depicts a system in efficiently mode to restore lost functionality;

FIG. 4 depicts an apparatus that includes memory having a first memory subchannel and a second memory subchannel; and

FIG. 5 depicts a method.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” may be directed to a low-power double data rate memory (LPDDR), which may include, but is not limited to, a memory under the Low-Power Double Data Rate Memory 6 standard. LPDDR memories may be or include synchronous dynamic random access memories (SDRAMS). To the extent that the principles and methods disclosed herein may be expressly directed to LPDDR 6 or later memories, it is emphasized that this disclosure should not be understood as being limited to LPDDDR6 or later memories, but rather to any memory comprising a plurality of subchannels (e.g., two 16-bit subchannels for concurrent addressing) that can be controlled by a single memory subsystem, such as via a multiplexer. The term “software” refers to any type of executable instruction, including firmware.

LPDDR generally describes a synchronous dynamic random-access memory that typically uses less power than conventional memory configurations. Various standards for LPDDR have been promulgated, often by the Joint Electron Device Engineering Council (JEDEC). A memory according to LPDDR, for example a memory according to the forthcoming LPDDR6 standard, may include an efficiency mode, which may permit a single memory subsystem to operate two different memory subchannels by switching between them, such as with a multiplexer.

A memory subsystem may refer to one or both of a memory physical interface or a memory controller. The memory physical interface (which may also be referred to as a PHY or a memory PHY), may refer to a hardware component that serves as an interface between the memory controller and the memory device (e.g., such as a memory subchannel). The memory physical interface may handle low-level electrical signaling and timing decisions that are necessary to manage data transfer between the memory controller and the memory subchannel. This may include, for example, receiving a digital instruction from the memory controller and translating the digital signal to an analog signal that can be used in the memory subchannel. The memory physical interface may include a clock multiplier (PLL), one or more data transceivers, and logic for tasks, which may include, for example, read/write leveling and de-skewing.

A memory controller may refer to a circuit that manages the flow of data entering and exiting the memory (or a memory subchannel in the configurations expressly disclosed herein). Memory controllers may include the necessary logic to read from and write to a memory subchannel. The memory controller may send commands to a memory physical interface, and the memory controller may receive from the memory physical interface data that has been read out from the memory. The memory controller and the memory physical interface together may be referred to herein as a memory subsystem.

A memory subchannel may refer to a division of a main memory channel, such as into two independent addressable pathways. For example, a sixty-four-bit memory may be configured into two, independent thirty-two-bit memory subchannels. Such a subchannel design may result in increased efficiency and reduced latency for the memory, since each subchannel is controlled by a corresponding memory subsystem, and these, for example, two memory subsystems may access the memory subchannels in parallel (e.g. concurrently).

During the manufacture of a memory subsystem, various errors may occur, which may lead to one or more parts of the memory subsystem being defective. Such errors may be the result of contamination or impurities in the manufacturing process (e.g. dust), misalignment, or any of a variety of other types of errors. However it occurs, the manufacturing process may yield a subsystem that is inoperative. This can occur in a variety of places such as the memory physical interface, the memory controller, an electrical connection between the memory controller in the memory physical interface, or an electrical connection between the memory physical interface in the memory. When such a defect occurs, it may be impossible or undesirable for the memory subsystem to control or interact with a corresponding memory subchannel. Conventionally, when this occurs, the corresponding memory subchannel is inactive, and the memory chip is considered defective. This may render the memory chip generally unsuitable for use and likely unable to be sold on the market.

Similarly, even where a memory subsystem is operational at and after the time of manufacture, various events can occur during the course of the memory subsystem's expected lifespan that may render the memory subsystem inoperative. Should such a defect occur, this would conventionally result in the corresponding memory subchannel being deemed unusable, which may directly lead to a determination that the memory chip itself is unusable.

Some memories may be capable of operating in an efficiency mode, in which a single subsystem is connected to two memory subchannels via a multiplexer and is configured to operate each of the memory subchannels. This efficiency mode has the advantage of saving energy, as two memory subchannels may be operated by a single memory subsystem, thereby allowing one memory subsystem to remain inactive.

This efficiency mode feature may permit dynamic switching between one and two interfaces to save power when bandwidth demand is low, or it may be used in a static fashion in which the system on chip (SoC) always connects a whole memory device to a single interface (e.g., a single 12b interface) to allow for an overall increased system memory capacity by connecting twice the number of memory devices to the same SoC memory interface width. This efficiency mode may be, for example, an efficiency mode in accordance with LPDDR6. This notwithstanding, the principles disclosed herein may be applied beyond LPDDR6 and are not limited thereto; they may be used, for example, in any memory technology in which a multiplexer can be used to reduce a total number of interfaces used while still maintaining accessibility to each memory.

Of note regarding this efficiency mode, such efficiency modes permit the continued operation of a memory device's full capacity, albeit at somewhat reduced bandwidth. Nevertheless, this bandwidth reduction is small, and in some cases may be considered trivial, and thus may be acceptable in exchange for the benefit of being able to continue to use the memory or memory chip. For example, many memory SoCs may include sixteen or more channels. Assuming hypothetically sixteen channels on the memory SOC, each channel represents 6.25% of the total available bandwidth. A memory operating in efficiency mode in which a single subsystem controls two different memory subchannels would result in a 6.25% reduction in total bandwidth, which would be expected to have a low impact on overall system performance and may be quite acceptable to many end-users.

In the following, an alternative use of the efficiency mode is described, in which a connection between the memory device subchannel and the faulted SoC channel (e.g., a portion of the memory subsystem or a connection between the memory subsystem and the memory subchannel) is disabled, and an adjacent SoC channel is used to communicate with the subchannel, thus not losing memory capacity in the system (e.g., thus maintaining full memory capacity, albeit with reduced bandwidth).

With respect to manufacturing defects, the defective memory subsystem (e.g., the defective memory controller, the defective physical interface, or any other defective portion of the subsystem) may be determined during a manufacturing stage and fused accordingly. Then, when the system boots, the basic input/output system (BIOS) may detect the configuration and may program the SoC, corresponding memory, and/or relevant subsystem to operate in efficiency mode. In this manner, an operational subsystem will control both its regularly corresponding memory subchannel and another memory subchannel that would otherwise correspond to the defective memory subsystem.

Should an existing defect not be detected during manufacturing, or should the defect develop after manufacture, the error may be detected during operation (e.g., in the field). In this case, the BIOS may detect a faulty channel and may attempt to determine whether the fault is in the SoC (e.g., due to device aging) or in the memory by enabling efficiency mode and checking whether the failure still exists. If enabling the efficiency mode remedies the fault (e.g., permits a corresponding subchannel to be used), the device can continue with the use of efficiency mode and enjoy full access to the memory subchannels, albeit with slightly reduced bandwidth.

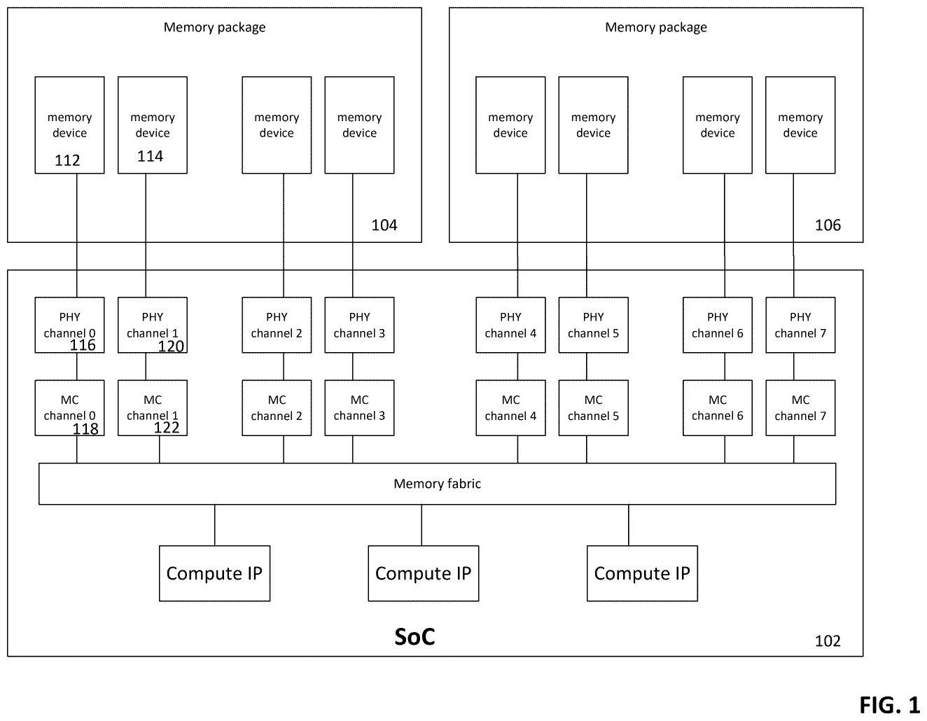

FIG. 1 depicts a fully-functional system with eight memory channels. The system includes an SoC 102, a first memory package 104, and a second memory package 106. The SOC 102 includes a plurality of memory subsystems. In this case, a zeroth memory subsystem includes a zeroth physical interface 116 and a zeroth memory controller 118. A first memory subsystem includes a first physical interface 120 and a first memory controller 122. The zeroth memory subsystem is configured to operate or control the zeroth memory subchannel 112, and the first memory subsystem is configured to operate or control the first memory subchannel 114. As each of the memory subchannels and subsystems are operational, no efficiency mode is entered.

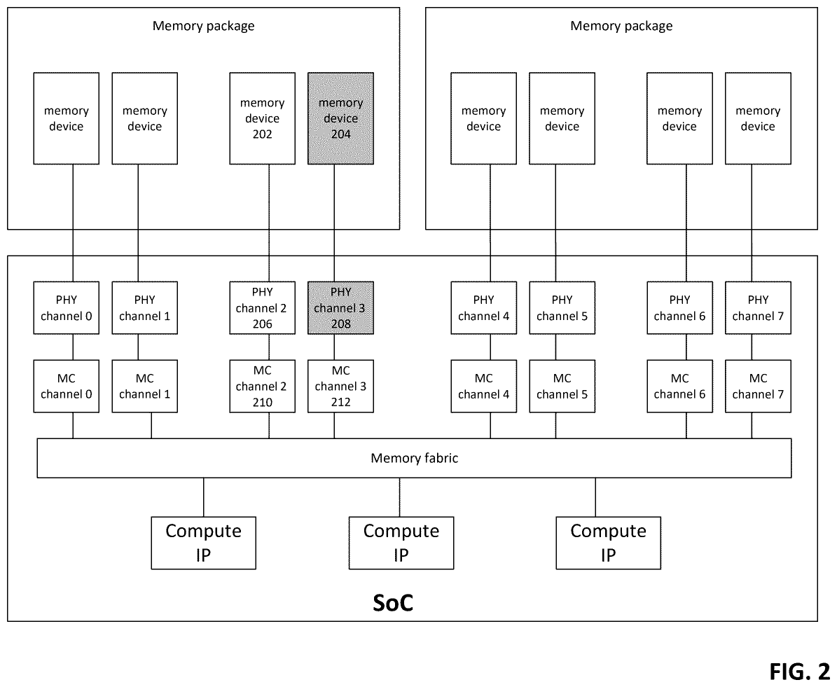

FIG. 2 depicts how a defect (e.g., in PHY channel 3) requires disabling a memory device, thus losing the capacity and bandwidth it provides. In this figure, a second memory subchannel 202 (the zeroth and first memory subchannels are unlabeled but are represented by the two squares labeled “memory device” to the left of the second memory subchannel 202) is operated by a second memory subsystem including second physical interface 206 and second memory controller 210. A third memory subchannel 204 is operated by a third memory subsystem including third physical interface 208 and third memory controller 212. In this figure, the third physical interface 208 is defective, which precludes the third memory subchannel 204 from being used. As such, the corresponding memory package has lost one fourth of its usable memory capacity. Conventionally, this chip would be unable to be marketed and may be discarded as defective.

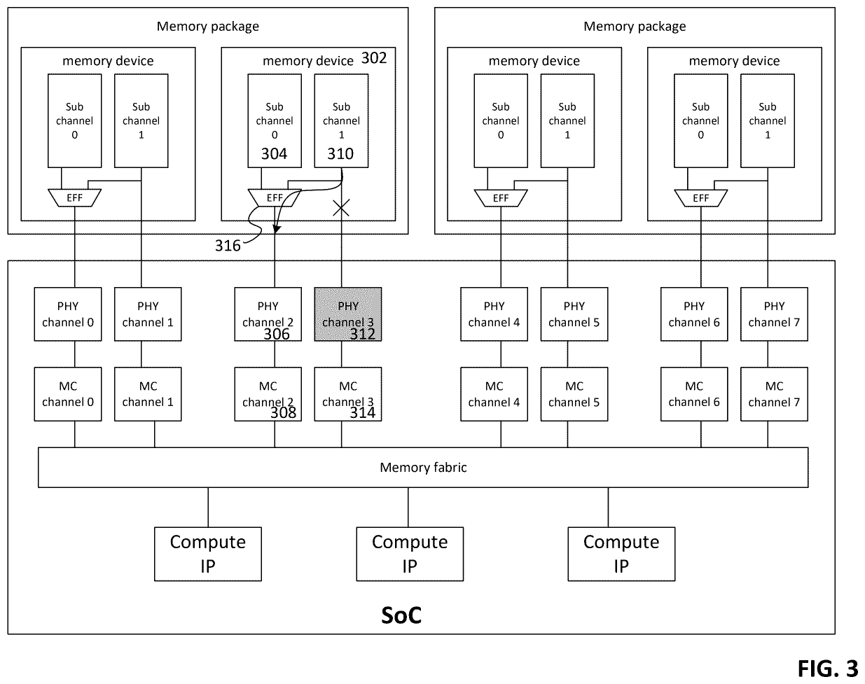

FIG. 3 depicts a system in efficiently mode to restore lost functionality. Memory device 302 includes a zeroth memory subchannel 304, which is operated by a second memory subsystem, which includes a second physical interface 306 and a second memory controller 308. Similarly, memory device 302 also includes a first memory subchannel 310, which is operated by a third memory subsystem, which includes a third physical interface 312 and a third memory controller 314. The third physical interface 312 is grayed out, indicating that it is defective. As such, the third physical interface 312 (and correspondingly the third memory subsystem that includes the third physical interface 312 and the third memory controller 314) cannot operate the second memory subchannel 310. The memory device includes a multiplexer 316, which is configured to selectively connect the second physical interface 306 to the zeroth memory subchannel 304 or the first memory subchannel 310. In this manner, the second memory subsystem can operate in control both the zeroth memory subchannel 304 and the first memory subchannel 310. Accordingly, each memory subchannel of the memory device 302 remains operational, albeit with slightly decreased bandwidth.

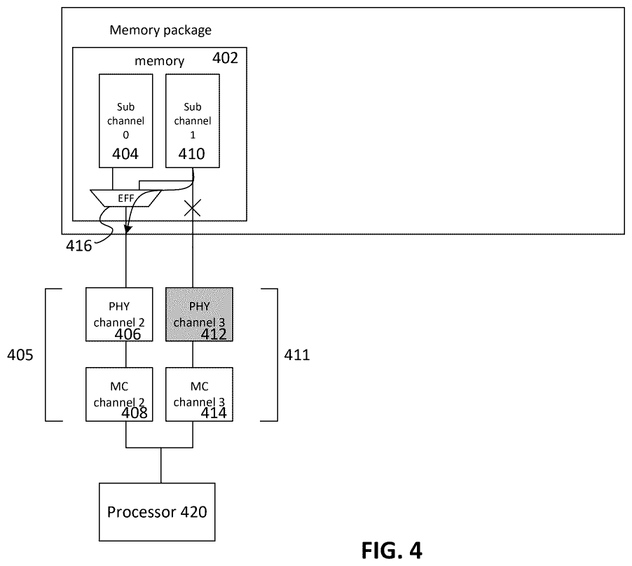

FIG. 4 depicts an apparatus that includes memory 402 that includes a first memory subchannel 404; and a second memory subchannel 410. A first memory subsystem 405 includes a first physical interface 406 and a first memory controller 408. The apparatus includes a multiplexer 416, which is configured to selectively connect the first memory subsystem 405 to the first memory subchannel 404 or the second memory subchannel 410. The apparatus includes a second memory subsystem 411, which may include a second physical interface 412 and a second memory controller 414, and which is connected to the second memory subchannel 410. The apparatus may include a processor 420, which may be configured to control the multiplexer to connect the first memory subsystem 405 to the first memory subchannel 404 according to a first operational mode, or to selectively connect the first memory subsystem 405 to the second memory subchannel 410 according to a second operational mode, based on whether a defect is detected in the second memory subsystem 411. In this manner, the first memory subsystem 405 may operate each of the first memory subchannel 404 and the second memory subchannel 410 as part of an efficiency mode. This may be achieved via multiplexer 416, which may switch a connection such that the first memory subsystem 405 is selectively connected to either the first subchannel 404 or the second subchannel 410. By selectively connecting the first memory subsystem 405 in this manner, the first memory subsystem 405 may read or write from either the first subchannel 404 or the second subchannel 410. This may be performed, for example, to compensate for a defective memory subsystem. For example, second memory subsystem 411, which may include the second physical channel 412 and the second memory controller 414, is defective by virtue of a defect in the second physical interface 412 (as shown by the gray shadowing). In a conventional configuration, the second memory subchannel 410 could not be operated. However, with the incorporation of the efficiency mode and the multiplexer 416, the first memory subsystem 405 can operate each of the memory subchannels.

The multiplexer operating according to the second operational mode may correspond to the first memory subsystem operating according to an efficiency mode as defined a Low Power Double Data Rate 6 standard as published by Joint Electron Device Engineering Council (JEDEC) Solid State Technology Association. Although this efficiency mode may be used in the corresponding literature to describe a low power mode in which a single memory subsystem operates to different memory subchannels, this efficiency mode may be utilized to compensate for a defect in a given memory subsystem. Thus, a processor 420 may be used to identify the defect in the memory subsystem and to implement the efficiency mode accordingly.

The processor 420 may be configured to control the multiplexer 416 to operate according to the first operational mode when no defect in the second memory subsystem is detected, and to control the multiplexer 416 to operate according to the second operational mode when the defect in the second memory subsystem 411 is detected. In this manner, the processor 420 may be configured to identify a defect in the second memory subsystem 411. This may occur by virtue of a second memory subsystem 411 defect being identified during manufacture and a corresponding bit indicating the defect is written to a memory or firmware. In this manner, the processor 420 identifying the defect includes the processor reading the corresponding bit and based on that bit, causing the apparatus to operate in efficiency mode such that the multiplexer 416 selectively switches the first memory subsystem 405 between the first memory subchannel 404 and the second memory subchannel 410.

Alternatively or additionally, the defect in the second memory subsystem 411 may occur after manufacture. In such instances, the processor 420 may perform one or more self-tests (e.g. a self-test in the application layer, a BIOS self-test, etc.), during which the defect is identified. Based on this identified defect, the processor 420 may cause the apparatus to operate in an efficiency mode and thus control the multiplexer 416 to selectively connect the first subsystem 405 between the first memory subchannel 404 and the second memory subchannel 410.

As described above, each of the first memory subsystem 405 and the second memory subsystem 411 may include a physical interface (406, 412), wherein each physical interface is configured to serialize and deserialize signals between a memory subchannel of the first memory-subchannel and the second memory subchannel, and a corresponding memory subsystem of the first memory subsystem or the second memory subsystem.

The processor may be configured to perform a test of the second memory subsystem, and the detection of the defect or the no detection of the defect may be or correspond to a result of the test. The test may be a self-test. In an alternative configuration, the test may be a test executed by any other system or outside element. In this manner, the test is not limited to a test performed by processor 420. It is sufficient if processor 420, which may control the multiplexer 416, receives the result of the test.

The first memory subchannel and the second memory subchannel may be memory subchannels according to (LPDDR6) as published by Joint Electron Device Engineering Council (JEDEC) Solid State Technology Association. It is, however, expressly stated that the principles and methods described herein are not limited to an apparatus that corresponds to a standard issued by JEDEC. Rather, a device corresponding to LPDDR6 is one of many configurations that may be used in efficiency mode or any mode similar to the efficiency mode disclosed herein, such that a single memory subsystem can access each of at least two memory subchannels.

Each of the first memory subsystem, the multiplexer, and the second memory subsystem may be configured as a system on chip (SoC). In this manner, they may be configured together on a single integrated circuit that combines each of these elements. The configuration as an SoC, however, is optional, and the principles and methods disclosed herein may be utilized within a memory that is not configured as an SoC.

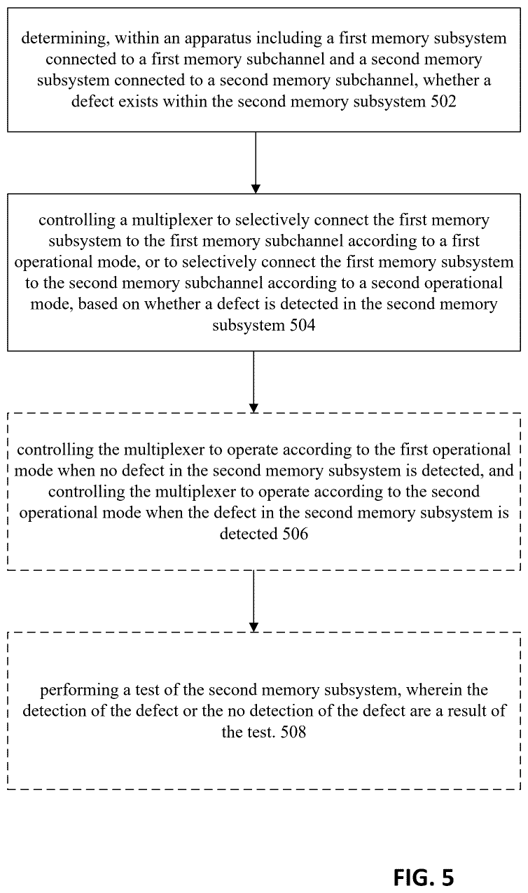

FIG. 5 depicts a method according to an embodiment. In this figure, a method includes determining, within an apparatus including a first memory subsystem connected to a first memory subchannel and a second memory subsystem connected to a second memory subchannel, whether a defect exists within the second memory subsystem 502; and controlling a multiplexer to selectively connect the first memory subsystem to the first memory subchannel according to a first operational mode, or to selectively connect the first memory subsystem to the second memory subchannel according to a second operational mode, based on whether a defect is detected in the second memory subsystem 504. The method may further include controlling the multiplexer to operate according to the first operational mode when no defect in the second memory subsystem is detected, and controlling the multiplexer to operate according to the second operational mode when the defect in the second memory subsystem is detected 506 and/or performing a test of the second memory subsystem, wherein the detection of the defect or the no detection of the defect are a result of the test 508. Note that optional configurations are depicted in dashed lines.

Further aspects of the disclosure will be described by way of example.

In Example 1, an apparatus, including a memory, including a first memory subchannel; and a second memory subchannel; a first memory subsystem; a multiplexer, configured to selectively connect the first memory subsystem to the first memory subchannel or the second memory subchannel; a second memory subsystem, connected to the second memory subchannel; and a processor, configured to control the multiplexer to connect the first memory subsystem to the first memory subchannel according to a first operational mode, or to selectively connect the first memory subsystem to the second memory subchannel according to a second operational mode, based on whether a defect is detected in the second memory subsystem.

In Example 2, the apparatus of Example 1, wherein the multiplexer operating according to the second operational mode includes the first memory subsystem operating according to an “efficiency mode” as defined a Low Power Double Data Rate 6 standard as published by Joint Electron Device Engineering Council (JEDEC) Solid State Technology Association.

In Example 3, the apparatus of Example 1 or 2, wherein the processor is configured to control the multiplexer to operate according to the first operational mode when no defect in the second memory subsystem is detected, and to control the multiplexer to operate according to the second operational mode when the defect in the second memory subsystem is detected.

In Example 4, the apparatus of any one of Examples 1 to 3, wherein each of the first memory subsystem and the second memory subsystem includes a physical interface, wherein each physical interface is configured to serialize and deserialize signals between a memory subchannel of the first memory-subchannel and the second memory subchannel, and a corresponding memory subsystem of the first memory subsystem or the second memory subsystem.

In Example 5, the apparatus of any one of Examples 1 to 4, wherein each of the first memory subsystem and the second memory subsystem includes a memory controller.

In Example 6, the apparatus of any one of Examples 1 to 5, wherein the processor is configured to perform a test of the second memory subsystem and wherein the detection of the defect or the no detection of the defect are a result of the test.

In Example 7, the apparatus of any one of Examples 1 to 6, wherein each of the first memory subchannel and the second memory subchannel is a logical and physical subdivision of a memory channel corresponding to the memory.

In Example 8, the apparatus of any one of Examples 1 to 7, wherein the first memory subchannel and the second memory subchannel are memory subchannels according to Low Power Double Data Rate 6 as published by Joint Electron Device Engineering Council (JEDEC) Solid State Technology Association.

In Example 9, the apparatus of any one of Examples 1 to 8, wherein each of the first memory subsystem, the multiplexer, and the second memory subsystem are configured as a system on chip.

In Example 10, a method, including: determining, within an apparatus including a first memory subsystem connected to a first memory subchannel and a second memory subsystem connected to a second memory subchannel, whether a defect exists within the second memory subsystem; controlling a multiplexer to selectively connect the first memory subsystem to the first memory subchannel according to a first operational mode, or to selectively connect the first memory subsystem to the second memory subchannel according to a second operational mode, based on whether a defect is detected in the second memory subsystem.

In Example 11, the method of Example 10, wherein the multiplexer operating according to the second operational mode includes the first memory subsystem operating according to an “efficiency mode” as defined a Low Power Double Data Rate 6 standard as published by Joint Electron Device Engineering Council (JEDEC) Solid State Technology Association.

In Example 12, the method of Example 10 or 11, further including controlling the multiplexer to operate according to the first operational mode when no defect in the second memory subsystem is detected, and controlling the multiplexer to operate according to the second operational mode when the defect in the second memory subsystem is detected.

In Example 13, the method of any one of Examples 10 to 12, wherein each of the first memory subsystem and the second memory subsystem includes a physical interface, wherein each physical interface is configured to serialize and deserialize signals between a memory subchannel of the first memory-subchannel and the second memory subchannel, and a corresponding memory subsystem of the first memory subsystem or the second memory subsystem.

In Example 14, the method of any one of Examples 10 to 13, wherein each of the first memory subsystem and the second memory subsystem includes a memory controller.

In Example 15, the method of any one of Examples 10 to 14, further including performing a test of the second memory subsystem, wherein the detection of the defect or the no detection of the defect are a result of the test.

In Example 16, the method of any one of Examples 10 to 15, wherein each of the first memory subchannel and the second memory subchannel is a logical and physical subdivision of a memory channel corresponding to the memory.

In Example 17, the method of any one of Examples 10 to 16, wherein the first memory subchannel and the second memory subchannel are memory subchannels according to Low Power Double Data Rate 6 as published by Joint Electron Device Engineering Council (JEDEC) Solid State Technology Association.

In Example 18, the method of any one of Examples 10 to 17, wherein each of the first memory subsystem, the multiplexer, and the second memory subsystem are configured as a system on chip.

In Example 19, an apparatus, including: a storage device, including: a first memory subchannel; and a second memory subchannel; a first memory subsystem; a selectable connector for selectively connecting the first memory subsystem to the first memory subchannel or the second memory subchannel; a second memory subsystem, connected to the second memory subchannel; and a processing device for controlling the multiplexer to connect the first memory subsystem to the first memory subchannel according to a first operational mode, or for selectively connecting the first memory subsystem to the second memory subchannel according to a second operational mode, based on whether a defect is detected in the second memory subsystem.

In Example 20, the apparatus of Example 19, wherein the selectable connector operating according to the second operational mode includes the first memory subsystem operating according to an “efficiency mode” as defined a Low Power Double Data Rate 6 standard as published by Joint Electron Device Engineering Council (JEDEC) Solid State Technology Association.

In Example 21, the apparatus of Example 19 or 20, wherein the processing device is for controlling the multiplexer to operate according to the first operational mode when no defect in the second memory subsystem is detected, and for controlling the multiplexer to operate according to the second operational mode when the defect in the second memory subsystem is detected.

In Example 22, the apparatus of any one of Examples 19 to 21, wherein each of the first memory subsystem and the second memory subsystem includes a physical interface, wherein each physical interface is configured to serialize and deserialize signals between a memory subchannel of the first memory-subchannel and the second memory subchannel, and a corresponding memory subsystem of the first memory subsystem or the second memory subsystem.

In Example 23, the apparatus of any one of Examples 19 to 22, wherein each of the first memory subsystem and the second memory subsystem includes a memory controller.

In Example 24, the apparatus of any one of Examples 19 to 23, wherein the processing device is for performing a test of the second memory subsystem and wherein the detecting of the defect or the no detection of the defect are a result of the test.

In Example 25, the apparatus of any one of Examples 19 to 24, wherein each of the first memory subchannel and the second memory subchannel is a logical and physical subdivision of a memory channel corresponding to the memory.

In Example 26, the apparatus of any one of Examples 19 to 25, wherein the first memory subchannel and the second memory subchannel are memory subchannels according to Low Power Double Data Rate 6 as published by Joint Electron Device Engineering Council (JEDEC) Solid State Technology Association.

In Example 27, the apparatus of any one of Examples 19 to 26, wherein each of the first memory subsystem, the selectable connector, and the second memory subsystem are configured as a system on chip.

In Example 28, a non-transitory computer readable medium, including instructions which, if executed by a processor, cause the processor to: determine, within an apparatus including a first memory subsystem connected to a first memory subchannel and a second memory subsystem connected to a second memory subchannel, whether a defect exists within the second memory subsystem; and control a multiplexer to selectively connect the first memory subsystem to the first memory subchannel according to a first operational mode, or to selectively connect the first memory subsystem to the second memory subchannel according to a second operational mode, based on whether a defect is detected in the second memory subsystem.

In Example 29, the non-transitory computer readable medium of Example 28, wherein the multiplexer operating according to the second operational mode includes the first memory subsystem operating according to an “efficiency mode” as defined a Low Power Double Data Rate 6 standard as published by Joint Electron Device Engineering Council (JEDEC) Solid State Technology Association.

In Example 30, the non-transitory computer readable medium of Example 28 or 29, wherein the instructions are further configured to cause the processor to control the multiplexer to operate according to the first operational mode when no defect in the second memory subsystem is detected, and controlling the multiplexer to operate according to the second operational mode when the defect in the second memory subsystem is detected.

In Example 31, the non-transitory computer readable medium of any one of Examples 28 to 30, wherein each of the first memory subsystem and the second memory subsystem includes a physical interface, wherein each physical interface is configured to serialize and deserialize signals between a memory subchannel of the first memory-subchannel and the second memory subchannel, and a corresponding memory subsystem of the first memory subsystem or the second memory subsystem.

In Example 32, the non-transitory computer readable medium of any one of Examples 28 to 31, wherein each of the first memory subsystem and the second memory subsystem includes a memory controller.

In Example 33, the non-transitory computer readable medium of any one of Examples 28 to 32, wherein the instructions are further configured to cause the processor to perform a test of the second memory subsystem, wherein the detection of the defect or the no detection of the defect are a result of the test.

In Example 34, the non-transitory computer readable medium of any one of Examples 28 to 33, wherein each of the first memory subchannel and the second memory subchannel is a logical and physical subdivision of a memory channel corresponding to the memory.

In Example 35, the non-transitory computer readable medium of any one of Examples 28 to 34, wherein the first memory subchannel and the second memory subchannel are memory subchannels according to Low Power Double Data Rate 6 as published by Joint Electron Device Engineering Council (JEDEC) Solid State Technology Association.

In Example 36, the non-transitory computer readable medium of any one of Examples 28 to 35, wherein each of the first memory subsystem, the multiplexer, and the second memory subsystem are configured as a system on chip.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. An apparatus, comprising:
a memory, comprising:
a first memory subchannel; and
a second memory subchannel;
a first memory subsystem;
a multiplexer, configured to selectively connect the first memory subsystem to the first memory subchannel or the second memory subchannel;
a second memory subsystem, connected to the second memory subchannel; and
a processor, configured to control the multiplexer to connect the first memory subsystem to the first memory subchannel according to a first operational mode, or to selectively connect the first memory subsystem to the second memory subchannel according to a second operational mode, based on whether a defect is detected in the second memory subsystem.

2. The apparatus of claim 1, wherein the multiplexer operating according to the second operational mode comprises the first memory subsystem operating according to an “efficiency mode” as defined a Low Power Double Data Rate 6 standard as published by Joint Electron Device Engineering Council (JEDEC) Solid State Technology Association.

3. The apparatus of claim 1, wherein the processor is configured to control the multiplexer to operate according to the first operational mode when no defect in the second memory subsystem is detected, and to control the multiplexer to operate according to the second operational mode when the defect in the second memory subsystem is detected.

4. The apparatus of claim 1, wherein each of the first memory subsystem and the second memory subsystem comprises a physical interface, wherein each physical interface is configured to serialize and deserialize signals between a memory subchannel of the first memory-subchannel and the second memory subchannel, and a corresponding memory subsystem of the first memory subsystem or the second memory subsystem.

5. The apparatus of claim 1, wherein each of the first memory subsystem and the second memory subsystem comprises a memory controller.

6. The apparatus of claim 1, wherein the processor is configured to perform a test of the second memory subsystem and wherein the detection of the defect or the no detection of the defect are a result of the test.

7. The apparatus of claim 1, wherein each of the first memory subchannel and the second memory subchannel is a logical and physical subdivision of a memory channel corresponding to the memory.

8. The apparatus of claim 1, wherein the first memory subchannel and the second memory subchannel are memory subchannels according to Low Power Double Data Rate 6 as published by Joint Electron Device Engineering Council (JEDEC) Solid State Technology Association or any subsequently published Low Power Double Data Rate standard.

9. The apparatus of claim 1, wherein each of the first memory subsystem, the multiplexer, and the second memory subsystem are configured as a system on chip.

10. A method, comprising:
determining, within an apparatus comprising a first memory subsystem connected to a first memory subchannel and a second memory subsystem connected to a second memory subchannel, whether a defect exists within the second memory subsystem;
controlling a multiplexer to selectively connect the first memory subsystem to the first memory subchannel according to a first operational mode, or to selectively connect the first memory subsystem to the second memory subchannel according to a second operational mode, based on whether a defect is detected in the second memory subsystem.

11. The method of claim 10, wherein the multiplexer operating according to the second operational mode comprises the first memory subsystem operating according to an “efficiency mode” as defined a Low Power Double Data Rate 6 standard as published by Joint Electron Device Engineering Council (JEDEC) Solid State Technology Association.

12. The method of claim 10, further comprising controlling the multiplexer to operate according to the first operational mode when no defect in the second memory subsystem is detected, and controlling the multiplexer to operate according to the second operational mode when the defect in the second memory subsystem is detected.

13. The method of claim 10, wherein each of the first memory subsystem and the second memory subsystem comprises a physical interface, wherein each physical interface is configured to serialize and deserialize signals between a memory subchannel of the first memory-subchannel and the second memory subchannel, and a corresponding memory subsystem of the first memory subsystem or the second memory subsystem.

14. The method of claim 10, wherein each of the first memory subsystem and the second memory subsystem comprises a memory controller.

15. The method of claim 10, further comprising performing a test of the second memory subsystem, wherein the detection of the defect or the no detection of the defect are a result of the test.

16. The method of claim 10, wherein each of the first memory subchannel and the second memory subchannel is a logical and physical subdivision of a memory channel corresponding to the memory.

17. The method of claim 10, wherein the first memory subchannel and the second memory subchannel are memory subchannels according to Low Power Double Data Rate 6 as published by Joint Electron Device Engineering Council (JEDEC) Solid State Technology Association.

18. The method of claim 10, wherein each of the first memory subsystem, the multiplexer, and the second memory subsystem are configured as a system on chip.

19. A non-transitory computer readable medium, comprising instructions which, if executed by a processor, cause the processor to:
determine, within an apparatus comprising a first memory subsystem connected to a first memory subchannel and a second memory subsystem connected to a second memory subchannel, whether a defect exists within the second memory subsystem; and
control a multiplexer to selectively connect the first memory subsystem to the first memory subchannel according to a first operational mode, or to selectively connect the first memory subsystem to the second memory subchannel according to a second operational mode, based on whether a defect is detected in the second memory subsystem.

20. The non-transitory computer readable medium of claim 19, wherein the multiplexer operating according to the second operational mode comprises the first memory subsystem operating according to an “efficiency mode” as defined a Low Power Double Data Rate 6 standard as published by Joint Electron Device Engineering Council (JEDEC) Solid State Technology Association.
